(19) United States
(12) Patent Application Publication
(10) Pub. No.: US 2008/0090185 A1
(43) Pub. Date: Apr. 17, 2008

(54) Method and apparatus for rinsing a substrate during lithographic development processing

(75) Inventors: Masahiko Harumoto, Kyoto (JP); Akira Yamaguchi, Kyoto (JP); Akhiro Hisai, Kyoto (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SOKUDO CO., LTD., Kyoto (JP)

(21) Appl. No.: 11/906,748

(22) Filed: Oct. 2, 2007

(30) Foreign Application Priority Data
Oct. 4, 2006 (JP) 2006-272558

(51) Int. Cl. G03F 7/26

(52) U.S. Cl. 430/432; 134/56 R

(57) ABSTRACT

The invention provides a method capable of eliminating occurrence of concentration difference in developer depending on position on a substrate surface when a developer on the substrate is replaced with a rinse; preventing occurrence of stain-like defects on a resist film surface; and reducing amount used of the developer. While a substrate is being rotated about a vertical axis by a rotation motor with held in a horizontal posture by a spin chuck, after the developer has been fed onto the resist film on the substrate surface from a developer discharge nozzle to conduct processing, the substrate continues to be rotated and thus the developer on the resist film is dispersed by a centrifugal force to be removed, and thereafter a rinse is fed onto the resist film from a rinse discharge nozzle to conduct rinsing.

### CROSS-REFERENCES TO RELATED APPLICATIONS

This application claims priority to Japanese Patent Application 2006-272558, filed Oct. 4, 2006, the disclosure of which is incorporated by reference in its entirety herein for all purposes.

### BACKGROUND OF THE INVENTION

The present invention relates to a substrate processing method and a substrate processing apparatus in which a developer is fed onto a resist film having been exposed and formed on the surface of a substrate such as semiconductor wafer, liquid crystal display glass substrate, photo-mask glass substrate, and optical disk substrate, to conduct processing.

In a conventional process of manufacturing a semiconductor device, a circuit pattern is formed on a resist film of a substrate employing lithography, for example, by the steps of applying a photo-resist on a silicon substrate, printing a circuit pattern onto a resist film on the substrate using an exposure device, and developing the resist film having been exposed with a developer. In the developing process among those steps, for example, while a substrate is being rotated in a vertical axis while held in a horizontal posture, a developer continues to be discharged onto the center of the substrate from a tip end outlet of a straight nozzle, and the developer is uniformly spread and applied over the entire surface of a resist film on the substrate surface, thereby developing the resist film having been exposed and formed on the substrate surface. In addition, recently, instead of the mentioned development method, such a development method has been widely used that with respect to a substrate in a still state of being held in the horizontal posture, while a slit nozzle having a slit-like outlet at the lower end face is being moved linearly in a direction orthogonal to the slit-like outlet, a developer is discharged onto a resist film on the substrate surface from the slit-like outlet, and the developer is spread forming a continuous film over the entire surface of the resist film, thereby developing the resist film (the so-called paddle phenomenon). The line width of a pattern to be formed on the resist film by these processing is controlled by adjusting the time period in which the developer continues to be discharged onto the substrate from the straight nozzle in the former development method, and by adjusting the time period of the developer being uniformly spread on the substrate in the paddle development. Therefore, in the former development method, when a predetermined discharge time period of the developer has elapsed, the supply of the developer onto the substrate is stopped; at the same time, a rinse (rinsing agent) such as a de-ionized water (DI water) is fed onto the resist film having been processed and formed on the substrate surface to conduct rinsing; and thereafter, the substrate is dried by spin-drying. Moreover, in the paddle development, for example, as disclosed in the Japanese Patent Publication (unexamined) No. 20508/1998, when a predetermined still time period after the developer has been uniformly spread (low-speed rotation time period when the substrate is rotated at low speed in the state that the developer is uniformly spread) has elapsed, the substrate is brought in rotation at high speed; a rinse is fed onto the substrate to conduct rinsing; and thereafter the substrate is dried by spin-drying.

In this respect, it has been conventionally considered that when there is a time period present between the development process and the rinsing process, a resin component of the resist having been dissolved into the developer remains on the resist film as scum, thereby leading to the occurrence of considerable development defects on the resist film. Therefore, in the former development method as mentioned above, when a predetermined discharge time period of the developer has elapsed, the supply of the developer onto the substrate is stopped, and at the same time, the rinse is fed onto the substrate to conduct rinsing, thus to rapidly replace the developer on the resist film with the rinse. However, in a chemically amplified resist that has been widely used recently, there is reported no example in which the resin component of the resist having been dissolved into the developer becomes a scum; while, there are reported many problems such as the occurrence of stain-like defects (referred to as satellites or cat paws) on the resist film surface. The occurrence of these stain-like defects is caused by the remaining developer on the resist film, being caused by the generation of a concentration difference in the developer depending on the position on the substrate surface on the occasion when the program proceeds to the development process from the rinsing process, and thus the developer is replaced by the rinse, e.g., DI water. Accordingly, the method having been desirable heretofore, that is, the method itself of replacing the developer with the rinse immediately after the development process is thought to be problematic.

Furthermore, in the conventional concept as to the former development method, a time period from the start of discharge of the developer onto the substrate until the discharge of the developer is stopped and then the developer on the substrate is replaced by the rinse, is considered a development time period. Thus, based on such a concept, the pattern line width of the resist film has been controlled by adjusting this time period. Accordingly, until going to the rinsing process, the developer continues to be discharged onto the resist film. Consequently, a large amount of developer has been used.

### SUMMARY OF THE INVENTION

The present invention has been made in view of the situations as described above, and has an object of providing a substrate processing method by which the occurrence of a concentration difference in developer depending on the position on a substrate surface on the occasion when the developer on the substrate is replaced with a rinse (rinsing agent) is eliminated; thus, the occurrence of stain-like defects on the resist film surface can be prevented; and the amount of the developer used can be reduced. The invention also has another object of providing a substrate processing apparatus with which the mentioned method can be preferably carried out.

According to an embodiment of the present invention, a substrate processing method is provided. The method includes performing a development process including rotating a substrate about a vertical axis in a horizontal posture and feeding a developer onto a resist film having been exposed and formed on a surface of the substrate, thereby processing the resist film. The method also includes performing a developer removal process including continuing the rotating the substrate about the vertical axis in the horizontal posture and dispersing the developer on the surface of the substrate by a centrifugal force. The method further includes thereafter rinsing the processed resist film and drying the rinsed and processed resist film by rotating the substrate about the vertical axis in the horizontal posture.

According to an alternative embodiment of the present invention, a substrate processing apparatus is provided. The substrate processing apparatus includes a substrate holder configured to hold the substrate in a horizontal posture and a substrate rotation device coupled to the substrate holder and configured to rotate the substrate about a vertical axis. The substrate processing apparatus also includes a developer discharge nozzle configured to discharge a developer onto a resist film having been exposed and formed on a surface of the substrate held by the substrate holder and a rinse discharge nozzle configured to discharge a rinse onto the resist film. The substrate processing apparatus further includes a control system coupled to the substrate rotation device, the developer discharge nozzle, and the rinse discharge nozzle and comprising a computer-readable medium storing a plurality of instructions for controlling a data processor to initiate a rinse process. The plurality of instructions includes instructions that cause the data processor to determine that the developer has been discharged onto the resist film, instructions that cause the data processor to provide a signal to the substrate rotation device to rotate the substrate about the vertical axis, thereby dispersing the developer by a centrifugal force, and instructions that cause the data processor to thereafter provide a signal to the rinse discharge nozzle to initiate a discharge of the rinse onto the resist film.

According to another embodiment of the present invention, a substrate processing method is provided. The method includes a development process in which while a substrate is being rotated about a vertical axis in a horizontal posture, a developer is fed onto a resist film having been exposed and formed on a surface of the substrate, to process the resist film; a rinsing process in which while the substrate is being rotated about the vertical axis in the horizontal posture, a rinse (rinsing agent) is fed onto the resist film having been processed and formed on the substrate surface; and a drying process in which the substrate is rotated about the vertical axis in the horizontal posture, to dry a resist film having been rinsed and formed on a substrate surface; and in which after the mentioned development process, there is included a developer removing process in which the substrate continues to be rotated about the vertical axis in the horizontal posture, and thus the developer remaining on the surface of the substrate is dispersed by a centrifugal force to be removed, and the mentioned rinsing process is conducted after this developer removing process.

The invention as described herein includes, during the development process, a position of feeding the developer is scanned from a center of the substrate to a circumferential edge thereof.

The invention as defined herein includes, during the developer removing process, a drying gas is fed onto the center of the substrate in rotation.

The invention as described herein includes, during the developer removing process, a drying gas is fed onto the center of the substrate in rotation, and a position of feeding the drying gas is scanned from a center of the substrate to a circumferential edge thereof.

According to a specific embodiment of the present invention, a substrate processing apparatus is provided. The substrate processing apparatus includes substrate holding means for holding a substrate in a horizontal posture; substrate rotation device causing the substrate that is held by this substrate holder to rotate about a vertical axis; a developer discharge nozzle discharging a developer onto a resist film having been exposed and formed on a surface of the substrate held by the mentioned substrate holder; and a rinse discharge nozzle discharging a rinse onto a resist film having been processed and formed on the substrate surface, and in which there is provided control means for controlling each of the mentioned substrate rotation device, developer discharge nozzle, and rinse discharge nozzle such that while the substrate is being rotated by the mentioned substrate rotation device, after the developer has been discharged onto the resist film having been exposed and formed on the substrate surface from the mentioned developer discharge nozzle to process the resist film, the substrate continues to be rotated, and thus the developer on the surface of the substrate is dispersed by a centrifugal force to be removed, and thereafter a rinse is discharged onto the resist film having been processed and formed on the substrate surface from the mentioned rinse discharge nozzle to conduct rinsing.

The invention as described herein includes an embodiment in which the mentioned developer discharge nozzle, while the developer is being discharged onto the surface of the substrate from an outlet thereof, is scanned from a position in which the outlet is opposed to the center of the surface to a position in which it is opposed to the circumferential edge of the substrate.

The invention as described herein further includes a gas jet nozzle blowing out a drying gas onto the resist film having been processed and formed on the substrate surface.

The invention as described herein includes an embodiment in which the mentioned gas jet nozzle, while a drying gas is being blown out onto the surface of the substrate from a jet hole thereof, is scanned from a position in which the jet hole is opposed to the center of the substrate to a position in which it is opposed to the circumferential edge of the substrate.

According to the substrate processing method described herein, because the substrate continues to be rotated after the development process, the developer on the surface of the substrate is dispersed by a centrifugal force to be removed. Therefore, less developer remains on the resist film on the substrate surface, or there will be no developer present on the resist film. In this state, when a rinse is fed onto the resist film on the substrate surface to conduct rinsing, the developer on the resist film is rapidly replaced with the rinse. Accordingly, since there will be a significantly less time period and region in which the concentration difference in the developer occurs depending on the position on a substrate surface, or since there is no developer on the resist film at a time point of starting the rinsing, the generation itself of the concentration difference in the developer depending on the position on the substrate surface does not occur. As a result, the occurrence of stain-like defects on the resist film surface caused by the remaining developer on the resist film is suppressed or eliminated.

Whereas, even if less developer remains on the resist film on the substrate surface, due to the presence of the developer on the resist film, a development reaction still proceeds until the rinsing is conducted. Furthermore, even if there is no developer on the resist film, insofar as the developer is present in an internal part of the resist film, the development reaction still proceeds until the rinsing is conducted. Thus, also during the time period in which the substrate is rotated after the supply of the developer onto the resist film on the substrate surface has been stopped, the development reaction still proceeds. Accordingly, even if the developer does not continue to be fed onto the resist film on the substrate surface in a conventional fashion, by adjusting the time of going to the rinsing process, a pattern line width of the resist film can be controlled.

As a result, in the substrate processing method provided according to embodiments of the present invention, the occurrence of stain-like defects on the resist film on the substrate surface can be prevented, and the amount used of the developer can be reduced.

In the processing method of the invention provided by other embodiments, because the position of feeding the developer is scanned from the center of the substrate to the circumferential edge thereof, the film thickness of the developer is decreased by degrees from the center of the substrate toward the circumferential edge. Therefore, the time period required to rotate the substrate after the development process to remove the developer from the surface of the substrate can be made shorter. As a result, in the processing method described herein, the time period necessary for a series of processing from the development process to the drying process can be shortened.

In the processing method of the invention provided by an alternative embodiment, because a drying gas is fed onto the center of the substrate in rotation, the film thickness of the developer at the center of the substrate comes to be smaller. Therefore, the time period required to rotate the substrate after the development process to remove the developer from the surface of the substrate can be made smaller. As a result, in the processing method of the invention described herein the time period necessary for a series of processing from the development process to the drying process can be shortened.

In the processing method of the invention described herein, because a drying gas is fed onto the center of the substrate in rotation, the film thickness of the developer at the center of the substrate comes to be smaller. In addition, due to that the position of feeding the drying gas is scanned from the center of the substrate to the circumferential edge, the film thickness of the developer is decreased by degrees from the center of the substrate toward the circumferential edge. Therefore, the time period required to rotate the substrate after the development process to remove the developer from the surface of the substrate can be made shorter. As a result, in the processing method of embodiments of the present invention, the time period necessary for a series of processing from the development process to the drying process can be shortened.

When using the substrate processing apparatus provided according to embodiments of the present invention, because after the developer has been discharged onto the resist film on the substrate surface from the developer discharge nozzle and thus the resist film has been processed, the substrate continues to be rotated by the substrate rotation device, so that the developer on the surface of the substrate is dispersed by the centrifugal force to be removed. Therefore, less developer remains on the resist film on the substrate surface, or there is no developer present on the resist film.

In this state, when a rinse is fed onto the resist film on the substrate surface from the rinse discharge nozzle to conduct rinsing, the developer on the resist film is rapidly replaced with the rinse. Accordingly, since there will be a significantly less time period and region in which the concentration difference in the developer occurs depending on the position on the substrate surface, or since there is no developer on the resist film at a time point of starting rinsing, the generation itself of the concentration difference in the developer depending on the position on the substrate surface does not occur. As a result, the occurrence of stain-like defects on the resist film surface caused by the remaining developer on the resist film is suppressed or eliminated.

Whereas, even if the substrate continues to be rotated by substrate rotation device after processing and thus less developer remains on the resist film on the substrate surface, due to the presence of the developer on the resist film, a development reaction still proceeds until the rinsing is conducted. Furthermore, even if there is no developer on the resist film, insofar as the developer is present in an internal part of the resist film, the development reaction still proceeds until the rinsing is conducted. Accordingly, even if the developer does not continue to be fed onto the resist film on the substrate surface from the developer discharge nozzle, by adjusting the time of feeding the rinse onto the resist film on the substrate surface from the rinse discharge nozzle, a pattern line width of the resist film can be controlled.

As a result, when using the substrate processing apparatus provided according to embodiments of the present invention, the processing method of the invention described herein is preferably carried out, thus enabling to prevent the occurrence of stain-like defects on the resist film on the substrate surface, as well as to reduce the amount used of the developer.

In the processing apparatus of the invention according to another embodiment, while the developer is being discharged onto the surface of the substrate from the outlet of the developer discharge nozzle, the developer discharge nozzle is scanned from the position in which the outlet thereof is opposed to the center of the substrate to the position in which it is opposed to the circumferential edge of the substrate, the film thickness of the developer is decreased by degrees from the center of the substrate toward the circumferential edge. Therefore, the time period required to rotate the substrate by the substrate rotation device after processing to remove the developer from the surface of the substrate can be made shorter. As a result, in the processing apparatus of the invention described herein, the time period necessary for a series of processing from the development process to the drying process can be shortened.

In the processing apparatus of the invention provided according to another alternative embodiment, because a drying gas is fed onto the center of the substrate in rotation from the gas jet nozzle, the film thickness of the developer at the center of the substrate comes to be smaller. Therefore, the time period required to rotate the substrate by the substrate rotation device after processing to remove the developer from the surface of the substrate can be made shorter. As a result, in the processing apparatus of the invention according to embodiments, the time period necessary for a series of processing from the development process to the drying process can be shortened.

In the processing apparatus of the invention according to yet another alternative embodiment, because a drying gas is fed onto the center of the substrate in rotation from the gas jet nozzle, the film thickness of the developer at the center of the substrate comes to be smaller. In addition, due to that while the drying gas is being blown out onto the surface of the substrate from the jet hole of the gas jet nozzle, the gas jet nozzle is scanned from the position in which the jet hole thereof is opposed to the center of the substrate to the position in which it is opposed to the circumferential edge of the substrate, the film thickness of the developer is decreased by degrees from the center of the substrate toward the circumferential edge. Therefore, the time period required to rotate the substrate by the substrate rotation device after processing to remove the developer from the surface of the substrate can be made shorter. As a result, in the processing apparatus of the invention described herein, the time period necessary for a series of processing steps from the development process to the drying process can be shortened.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic longitudinally sectional view illustrating one example of a construction of a processing apparatus for use in carrying out a substrate processing method according to the present invention.

FIG. 2 is a schematic plan view of the processing apparatus illustrated in FIG. 1.

FIG. 3 is a schematic longitudinally sectional view illustrating another construction example of a processing apparatus for use in carrying out the substrate processing method according to this invention.

FIG. 4 is a schematic plan view of the processing apparatus illustrated in FIG. 3.

FIG. 5 is a graphic chart showing the change in the number of defects in the case of changing the time period of rotation of a substrate until going to a rinsing process when the substrate continues to be rotated after the development process to remove the developer.

### DETAILED DESCRIPTION OF SPECIFIC EMBODIMENTS

The best mode for carrying out the present invention is hereinafter described referring to the accompanying drawings.

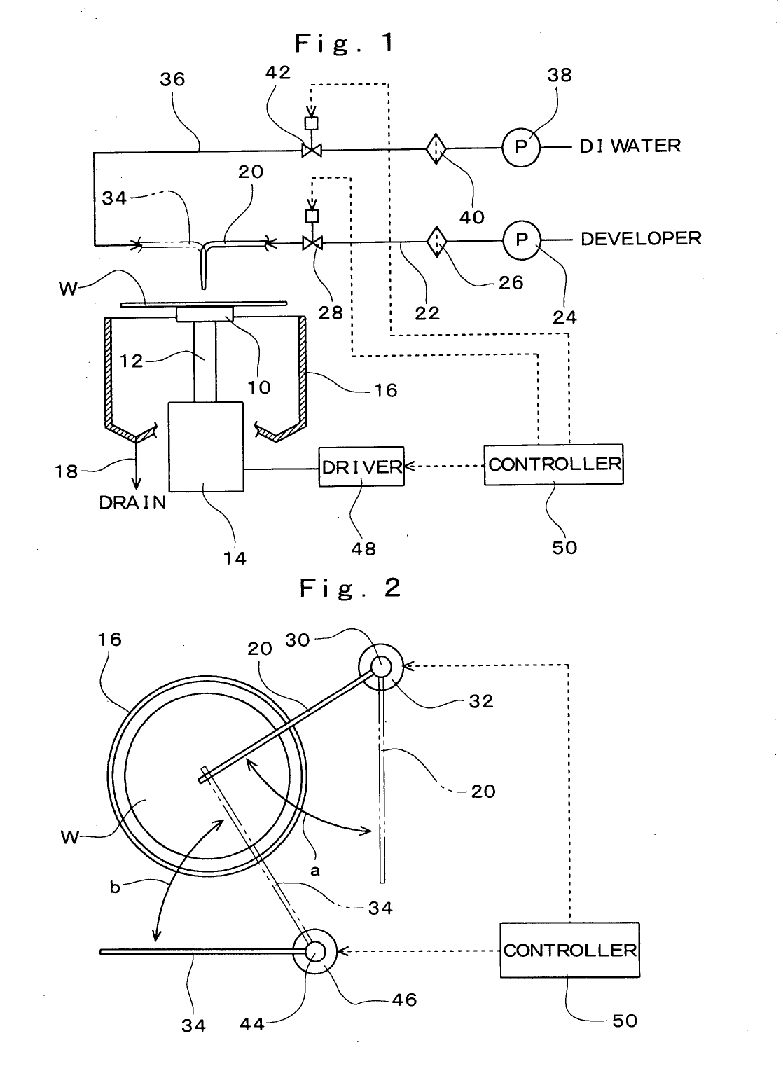

FIGS. 1 and 2 illustrate one example of a construction of a processing apparatus for use in carrying out a substrate processing method according to embodiments of the present invention, and in which FIG. 1 is a longitudinally sectional view illustrating a schematic construction of a processing apparatus, and FIG. 2 is a plan view thereof.

This processing apparatus includes a spin chuck 10 holding a substrate W in a horizontal posture, a spindle 12 to the upper end of which the spin chuck 10 is fixed and which is vertically supported, and a rotation motor 14 of which rotary shaft is connected to the spindle 12 and which causes the spin chuck 10 and the spindle 12 to rotate about a vertical axis. There is disposed around the spin chuck 10 a circular cup 16 so as to surround the substrate W on the spin chuck 10. The cup 16 is supported so as to be capable of reciprocating in a vertical direction by a support mechanism, not illustrated. A drain tube 18 is connected in communication to the bottom of the cup 16.

There is disposed in the vicinity of the cup 16 a developer discharge nozzle 20 formed of a straight nozzle discharging a developer onto the substrate W from an outlet at a tip end. The developer discharge nozzle 20 is channel-connected to a developer supply source through a developer feed tube 22, and a pump 24, a filter 26 and a switching control valve 28 are interposed in this developer feed tube 22. The developer discharge nozzle 20 is held by a nozzle holding part 30 rotatably in a horizontal plane, and is turned in the horizontal plane by a rotation drive mechanism 32. Furthermore, the developer discharge nozzle 20, as indicated by the arrow a in FIG. 2, is constructed so as to reciprocate between a waiting position indicated by the two-dot chain line and being out of place to the outside from the cup 16, and a discharge position indicated by the solid line in which the outlet is located right above the center of the substrate W. In the state that the outlet is located right above the center of the substrate W as indicated by the solid line, the developer is discharged from the tip end outlet onto the surface center of the substrate W.

In addition, there is disposed in the vicinity of the cup 16 a DI water discharge nozzle 34 discharging a rinse (rinsing agent), for example, DI water onto the substrate W from the outlet at a tip end. The DI discharge nozzle 34 is channel-connected to a DI water supply source through a DI water feed tube 36, and a pump 38, a filter 40 and a switching control valve 42 are interposed in this DI water feed tube 36. The DI water discharge nozzle 34 is held by a nozzle holding part 44 rotatably in a horizontal plane, and is turned in the horizontal plane by a rotation drive mechanism 46. Further, the DI water discharge nozzle 34, as indicated by the arrow b in FIG. 2, is constructed so as to reciprocate between a waiting position indicated by the solid line and being out of place to the outside from the cup 16, and a discharge position indicated by the two-dot chain line in which the outlet is located right above the center of the substrate W. In the state that the outlet is located right above the center of the substrate W as indicated by the two-dot chain line, the DI water is discharged onto the surface center of the substrate W from the tip end outlet.

Moreover, this processing apparatus is provided with a controller 50 acting to control respective switching operations of the switching control valves 28 and 42, to control respective rotation drive mechanisms 32 and 46 of the developer discharge nozzle 20 and the DI water discharge nozzle 34, or further to control a driver 48 of the rotation motor 14 to adjust the number of revolutions of the rotation motor 14 and thus the rotation speed of the substrate W.

Now, one example of a processing operation by means of the processing apparatus illustrated in FIGS. 1 and 2 is described.

When the substrate W on the surface of which a resist film having been exposed is formed, is held by the spin chuck 10, the developer discharge nozzle 20 is turned, and thus the tip end outlet of the developer discharge nozzle 20 is moved to the position right above the center of the substrate W. Then, while the substrate W is being rotated at a rotation speed of, for example, 500 rpm to 1,000 rpm, a developer is discharged and fed onto the center of the substrate W from the tip end outlet of the developer discharge nozzle 20. The developer having been fed onto the substrate W is spread over the entire surface of the substrate W to be applied onto the resist film so as to cover the entire surface of the resist film. After a predetermined time period has elapsed, for example, five to ten seconds have elapsed, the supply of the developer onto the substrate W is stopped, and the developer discharge nozzle 20 is turned to the original waiting position indicated by the two-dot chain line in FIG. 2 to be returned. On the other hand, even after the supply of the developer onto the substrate W has been stopped, the substrate W continues to rotate. For example, for 30 seconds when the substrate W is rotated at a rotation speed of 1,000 rpm, 60 seconds when the substrate W is rotated at a rotation speed of 500 rpm, and 90 seconds to 120 seconds when the substrate W is rotated at a rotation speed of 300 rpm, the substrate W continues to rotate. At this time, it is preferable that immediately after the supply of the developer onto the substrate W has been stopped, the substrate W is rotated at high speed, for example, at a rotation speed of 2,000 rpm to 3,000 rpm, only for a short time period, for example, for only one second, and thereafter switched to rotate at low speed, for example, at a rotation speed of 300 rpm to 500 rpm. Incidentally, during the rotation of the substrate W, the cup 16 is lifted.

After the supply of the developer onto the substrate W has been stopped to end the development process, the substrate W continues to be rotated even after the development process, whereby the developer on the surface of the substrate W is dispersed by a centrifugal force to be removed. Therefore, less developer remains on the resist film on the surface of the substrate W, or there is no developer present on the resist film. Then, while the substrate W further continuing to rotate, the DI water discharge nozzle 34 is turned, and the outlet at the tip end of the DI water discharge nozzle 34 is moved to the position right above the center of the substrate W. Subsequently, while the substrate W is being rotated, the DI water is discharged and fed onto the center of the substrate W from the tip end outlet of the DI water discharge nozzle 34. This rinsing is conducted for about 10 seconds to 15 seconds while the substrate W is being rotated at a rotation speed of, for example, 1,000 rpm. At this time, it is preferable that the substrate W is rotated at high speed for a moment shortly after the start of rinsing, and thereafter rotated at a reduced speed. With such operation, more impurities are flowed out from the resist film. When the rinsing process is ended, the supply of the DI water onto the substrate W is stopped, and the DI water discharge nozzle 34 is turned and returned to the original waiting position indicated by the solid line in FIG. 2. Then, the rotation speed of the substrate W is switched to high speed, to dry the substrate W by spin-drying. On this occasion, the cup 16 is lifted. When the drying of the substrate W is ended, the substrate W is removed from the spin chuck 10 to be transported out of the apparatus.

As mentioned above, in embodiments in which less developer remains on the resist film on the surface of the substrate W, or there is no developer present on the resist film, the DI water is fed onto the resist film on the surface of the substrate W to be subjected to the rinsing, the developer on the resist film is to be rapidly replaced with the DI water. Therefore, since there is significantly less time period and region in which the concentration difference of the developer occurs depending on the position on the substrate surface, or since there is no developer on the resist film at a time point of starting rinsing, the generation itself of the concentration difference in the developer depending on the position on the substrate surface does not occur. As a result, the occurrence of stain-like defects on the resist film surface caused by the remaining developer on the resist film can be prevented.

Whereas, even if less developer remains on the resist film on the surface of the substrate W, due to the presence of the developer on the resist film, a development reaction still proceeds until the DI water is fed onto the resist film to make rinsing. Furthermore, even if there is no developer on the resist film, insofar as the developer is present in an internal part of the resist film, the development reaction still proceeds until the rinsing is conducted. Thus, also during the time period in which the substrate W is in rotation after the development process, the development reaction still proceeds. Accordingly, even if the developer does not continue to be fed onto the resist film in a conventional fashion, by adjusting the time of going to the rinsing process, a pattern line width of the resist film can be controlled.

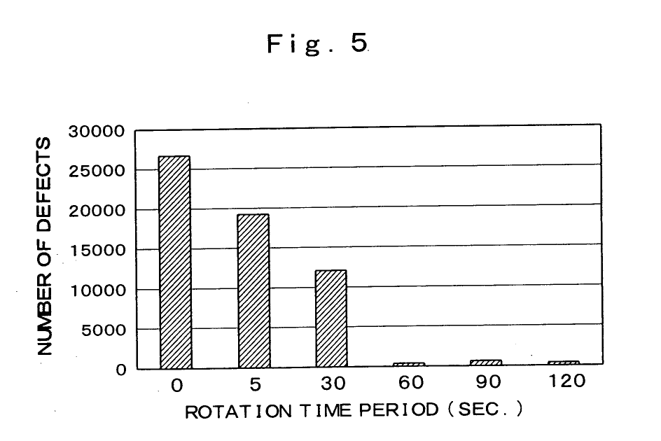

FIG. 5 is a graphic chart showing the change in the number of defects in the case of changing the time period of rotation of a substrate until going to the rinsing process when the substrate continues to be rotated after the development process to remove the developer. Test conditions are the rotation speed of the substrate at the time of processing: 300 rpm to 500 rpm; the rotation speed of the substrate after processing: 300 rpm to 500 rpm; the time period of discharge of a rinse (DI water): 10 seconds; the rotation speed of the substrate at the time of rinsing: 1,000 rpm; a drying time period of the substrate by spin-drying: 10 seconds; and the rotation speed of the substrate at the time of drying: 4,000 rpm. As is understood from the results shown in FIG. 5, when rinsing is conducted without rotation of the substrate to remove the developer after processing the number of defects was tens of thousands; while, when the substrate is rotated for 60 seconds to 120 seconds after processing, the number of defects was significantly reduced (350 numbers to 660 numbers). Incidentally, when the substrate is rotated for too long time period after processing, as compared with the case where the substrate is rotated only for an appropriate time period, the number of defects is increased.

Additionally, although in the above-mentioned embodiment, in the development process, the tip end outlet of the developer discharge nozzle 20 is moved to the position right above the center of the substrate W to be stopped, and the developer is discharged and fed onto the center of the substrate W from tip end outlet of the developer discharge nozzle 20, it is preferable that while the developer is being discharged onto the surface of the substrate W from the outlet of the developer discharge nozzle 20, the developer discharge nozzle 20 is scanned from the position in which the outlet thereof is opposed to the center of the substrate W to the position in which it is opposed to a circumferential edge of the substrate W. By making such processing operation, a film thickness of the developer is decreased by degrees from the center of the substrate W toward the circumferential edge. Therefore, the time period required to rotate the substrate W to remove the developer from the surface of the substrate W after the development process, can be made shorter, thus enabling to shorten a time period necessary for a series of processing from the development process to the drying process. In addition, it is preferable that while the developer is being discharged onto the surface of the substrate W from the outlet of the developer discharge nozzle 20, the developer discharge nozzle 20 is scanned from the position in which the outlet thereof is opposed to the circumferential edge of the substrate W to the position in which it is opposed to the center of the substrate W; and thereafter the developer discharge nozzle 20 is scanned from the position in which this outlet is opposed to the center of the substrate W to the original position in which it is opposed to the circumferential edge of the substrate W. Likewise, it is preferable that while the developer is being discharged onto the surface of the substrate W from the outlet of the developer discharge nozzle 20, the developer discharge nozzle 20 is scanned from the position in which the outlet thereof is opposed to the circumferential edge of the substrate W to, through the position in which it is opposed to the center of the substrate W, and to the position in which it is opposed to the circumferential edge of the substrate W. Moreover, it is preferable that the rotation speed of the substrate is changed for each process, or is changed in one process.

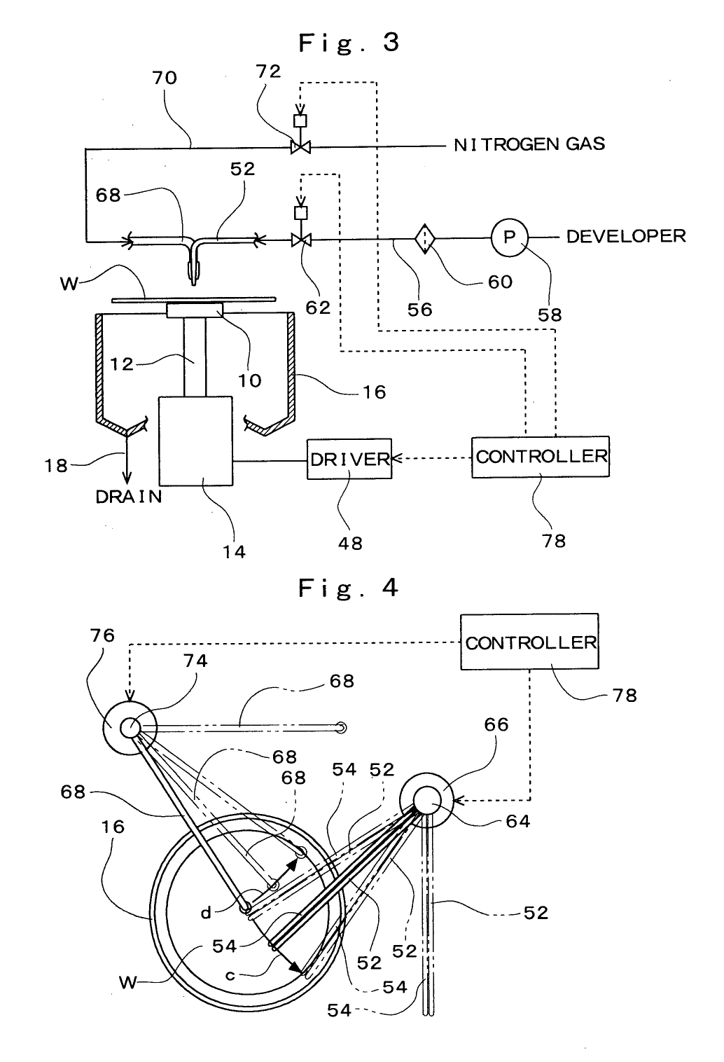

Now, FIGS. 3 and 4 illustrate another construction example of a processing apparatus for use in carrying out a substrate processing method according to the invention. FIG. 3 is a longitudinally sectional view illustrating a schematic construction of the processing apparatus, and FIG. 4 is a plan view thereof. In FIGS. 3 and 4, components and members designated by the same reference numerals as those in FIGS. 1 and 2 have the same functions and operations as those of the above-mentioned components and members described in FIGS. 1 and 2, and further descriptions thereof are omitted.

In this processing apparatus, there are disposed in the vicinity of the cup 16 a developer discharge nozzle 52 that is formed of a straight nozzle discharging a developer onto a substrate W from an outlet at a tip end, and a DI water discharge nozzle 54 (not illustrated in FIG. 3) discharging a rinse, for example, a DI water onto the substrate W from an outlet at a tip end. The developer discharge nozzle 52 is channel-connected to a developer supply source through a developer feed tube 56, and a pump 58, a filter 60 and a switching control valve 62 are interposed in the developer feed tube 56. Furthermore, the DI water discharge nozzle 54, not illustrated, is channel-connected to a DI water supply source through a DI water feed tube, and a pump, a filter and a switching control valve are interposed in the DI water feed tube (refer to FIG. 1). The developer discharge nozzle 52 and the DI water discharge nozzle 54 are held by a common nozzle holding part 64 rotatably in a horizontal plane, and are made to turn in the horizontal plane by a rotation drive mechanism 66. Further, the developer discharge nozzle 52, while the developer is being discharged onto the surface of the substrate W from the outlet at the tip end, as illustrated by the arrow c in FIG. 4, is scanned from the position in which the outlet is opposed to the center of the substrate W to the position in which it is opposed to the circumferential edge of the substrate W. Moreover, the developer discharge nozzle 52 and the DI water discharge nozzle 54 are returned to a waiting position out of place to the outside from the cup 16 as indicated by the two-dot chain line.

Moreover, there is disposed in the vicinity of the cup 16 a gas jet nozzle 68 blowing out a drying gas, for example, nitrogen gas onto the substrate W from a jet hole at a tip end. The gas jet nozzle 68 is channel-connected to a nitrogen gas supply source through a gas feed tube 70, and a switching control valve 72 is interposed in the gas feed tube 70. The gas jet nozzle 68 is held by a nozzle holding part 74 rotatably in a horizontal plane, and is made to turn in the horizontal plane by a rotation drive mechanism 76. In addition, the gas jet nozzle 68, while the nitrogen gas is being blown out onto the surface of the substrate W from the jet hole at the tip end, as indicated by the arrow d in FIG. 4, is scanned from the position in which the jet hole is opposed to the center of the substrate W to the position in which it is opposed to the circumferential edge of the substrate W. Furthermore, the gas jet nozzle 68 is constructed so as to reciprocate between a waiting position out of place to the outside from the cup 16 as indicated by the two-dot chain line, and a position in which the jet hole is located right above the center of the substrate W. In addition, this processing apparatus is provided with a controller 78 acting to control respective switching operations of the switching control valves 62 and 68, to control both of the rotation drive mechanism 66 for the developer discharge nozzle 52 and DI water discharge nozzle 54, and the rotation drive mechanism 76 of the gas jet nozzle 68, and further to control a driver 48 of the rotation motor 14 to adjust the number of revolutions of the rotation motor 14 and thus the rotation speed of the substrate.

Now, one example of the processing operation by means of the processing apparatus illustrated in FIGS. 3 and 4 are described.

When the substrate W on the surface of which the resist film having been exposed is formed, is held by the spin chuck 10, the developer discharge nozzle 52 (and the DI water discharge nozzle 54) is turned, and the tip end outlet of the developer discharge nozzle 52 is moved to the position right above the center of the substrate W. Then, the substrate W is brought in rotation at low speed, for example, at a rotation speed of 500 rpm to 1,000 rpm, and while the developer is being discharged onto the surface of the substrate W from the tip end outlet of the developer discharge nozzle 52, the developer discharge nozzle 52 is scanned from the position in which the outlet thereof is opposed to the center of the substrate W to the position in which it is opposed to the circumferential edge of the substrate W. Then, when the outlet of the developer discharge nozzle 52 has reached the position in which the outlet is opposed to the circumferential edge of the substrate W, the supply of the developer onto the substrate W is stopped, and the developer discharge nozzle 52(and the DI water discharge nozzle 54) is turned and returned to the original waiting position indicated by the two-dot chain line in FIG. 4.

Whereas, even after the supply of the developer onto the substrate W has been stopped, in the same manner as in the above-mentioned apparatus illustrated in FIGS. 1 and 2, the substrate W continues to rotate. By this operation, the developer on the surface of the substrate W is dispersed by a centrifugal force to be removed. Further, the gas jet nozzle 68 is turned, and the jet hole of the gas jet nozzle 68 is moved to the position right above the center of the substrate W. Then, while a nitrogen gas is being blown out onto the substrate W from the jet hole of the gas jet nozzle 68, the gas jet nozzle 68 is scanned from the position in which the jet hole thereof is opposed to the center of the substrate W to the position in which it is opposed to the circumferential edge of the substrate W. In this manner, due to that while the nitrogen gas is being blown out onto the surface of the substrate W from the jet hole of the gas jet nozzle 68, the gas jet nozzle 68 is scanned from the position in which the jet hole thereof is opposed to the center of the substrate W to the position in which it is opposed to the circumferential edge of the substrate W, the film thickness of the developer on the resist film is decreased from the center of the substrate W toward the circumferential edge. Therefore, the time period required to remove the developer from the resist film becomes shorter. When the jet hole of the gas jet nozzle 68 has reached the position of being opposed to the circumferential edge of the substrate W, the supply of the nitrogen gas from the gas jet nozzle 68 onto the substrate W is stopped, and the gas jet nozzle 68 is turned and returned to the original waiting position indicated by the two-dot chain line in FIG. 4.

While the substrate W continues to be rotated, for example, the substrate W is being rotated at a rotation speed of 1,000 rpm, the DI water discharge nozzle 54 (and the developer discharge nozzle 52) is turned, the tip end outlet of the DI water discharge nozzle 54 is moved to the position right above the center of the substrate W, and the DI water is discharged and fed onto the center of the substrate W from the tip end outlet of the DI water discharge nozzle 54. When the rinsing process is ended, the supply of the DI water onto the substrate W is stopped, and then the DI water discharge nozzle 54 (and the developer discharge nozzle 52) is turned and returned to the original position indicated by the two-dot chain line in FIG. 4. Further, the rotation speed of the substrate W is switched to high speed, to dry the substrate W by spin-drying. At this time, the cup is lifted. When the drying of the substrate is ended, the substrate W is removed from the spin chuck 10 to be transported out of the apparatus.

Also in the processing apparatus illustrated in FIGS. 3 and 4, in the state that less developer remains on the resist film on the surface of the substrate W or that there is no developer present on the resist film, the DI water is fed onto the resist film on the surface of the substrate W to conduct rinsing. Thus, in the same manner as in the apparatus illustrated in FIGS. 1 and 2, the occurrence of stain-like defects on the resist film surface caused by the remaining developer on the resist film is prevented. In addition, even if the developer does not continue to be fed onto the resist film, by adjusting the time of going to the rinsing process, a pattern line width of the resist film can be controlled. Moreover, in the processing apparatus illustrated in FIGS. 3 and 4, due to that the substrate W is rotated after the processing, the time period required to remove the developer from the resist film can be made shorter, so that a throughput can be improved.

Incidentally, although in the above-mentioned embodiment, in the development process, while the developer is being discharged onto the surface of the substrate W from the outlet of the developer discharge nozzle 52, the developer discharge nozzle 52 is scanned from the position in which the outlet thereof is opposed to the center of the substrate W to the position in which it is opposed to the circumferential edge of the substrate W, it is preferable that the tip end outlet of the developer discharge nozzle 52 is moved to the position right above the center of the substrate W to be stopped, and the developer is discharged and fed onto the center of the substrate W from the tip end outlet of the developer discharge nozzle 52. In addition, although while the nitrogen gas is being blown out onto the surface of the substrate W from the jet hole of the gas jet nozzle 68, the gas jet nozzle 68 is scanned from the position in which the jet hole thereof is opposed to the center of the substrate W to the position in which it is opposed to the circumferential edge of the substrate W, it is preferable that the jet hole of the gas jet nozzle 68 is moved to the position right above the center of the substrate W to be stopped, and the nitrogen gas is blown out just for a moment onto the center of the substrate W, or continues to be blown out. Furthermore, it is preferable that the timing in which the nitrogen gas starts to be blown out onto the surface of the substrate W from the gas jet nozzle 68 is before the outlet of the developer discharge nozzle 52 has reached the position opposed to the circumferential edge of the substrate W to stop the supply of the developer onto the substrate W. In addition, it is preferable that the speed of scanning of the developer discharge nozzle 52 and the gas jet nozzle 68 is constant, or varied. For example, it is preferable that the speed of the developer discharge nozzle 52 is gradually decreased or reduced stepwise as the developer discharge nozzle 52 is moved from the center position of the substrate to the circumferential edge position.

What is claimed is:

1. A substrate processing method comprising:
performing a development process comprising:
rotating a substrate about a vertical axis in a horizontal posture; and
feeding a developer onto a resist film having been exposed and formed on a surface of the substrate, thereby processing the resist film;
performing a developer removal process comprising:
continuing the rotating the substrate about the vertical axis in the horizontal posture; and
dispersing the developer on the surface of the substrate by a centrifugal force;
thereafter rinsing the processed resist film; and
drying the rinsed and processed resist film by rotating the substrate about the vertical axis in the horizontal posture.

2. The substrate processing method of claim 1 wherein the developer removal process is performed after the development process.

3. The substrate processing method of claim 1 further comprising scanning a position of feeding the developer from a center of the substrate to a circumferential edge thereof during the development process.

4. The substrate processing method of claim 1 wherein the developer removal process further comprises feeding a drying gas onto a center of rotation of the substrate.

5. The substrate processing method of claim 4 wherein the developer removal process further comprises scanning a position of feeding the drying gas from the center of rotation of the substrate to a circumferential edge thereof.

6. The substrate processing method of claim 1 wherein feeding the developer onto the resist film comprises dispensing the developer through a developer discharge nozzle including a slit nozzle having a slit-like outlet at a lower end face.

7. The substrate processing method of claim 1 wherein feeding the developer onto the resist film comprises dispensing the developer through a developer discharge nozzle including a straight nozzle having a tip end outlet.

8. A substrate processing apparatus comprising:
a substrate holder configured to hold the substrate in a horizontal posture;
a substrate rotation device coupled to the substrate holder and configured to rotate the substrate about a vertical axis;
a developer discharge nozzle configured to discharge a developer onto a resist film having been exposed and formed on a surface of the substrate held by the substrate holder; and
a rinse discharge nozzle configured to discharge a rinse onto the resist film; and
a control system coupled to the substrate rotation device, the developer discharge nozzle, and the rinse discharge nozzle and comprising a computer-readable medium storing a plurality of instructions for controlling a data processor to initiate a rinse process, the plurality of instructions comprising:
instructions that cause the data processor to determine that the developer has been discharged onto the resist film;
instructions that cause the data processor to provide a signal to the substrate rotation device to rotate the substrate about the vertical axis, thereby dispersing the developer by a centrifugal force; and
instructions that cause the data processor to thereafter provide a signal to the rinse discharge nozzle to initiate a discharge of the rinse onto the resist film.

9. The substrate processing apparatus of claim 8 wherein the computer-readable medium further stores:
instructions that cause the data processor to provide a signal to the developer discharge nozzle to scan from a from a position in which the outlet is opposed to the center of the surface to a position in which it is opposed to the circumferential edge of the substrate.

10. The substrate processing apparatus of claim 8 further comprising a gas jet nozzle configured to blow out a drying gas onto the resist film.

11. The substrate processing apparatus of claim 10 wherein the computer-readable medium further stores instructions that cause the data processor to provide a signal to the gas jet nozzle to scan from a position in which the jet hole is opposed to a center of the substrate to a position in which it is opposed to a circumferential edge of the substrate.

12. The substrate processing apparatus of claim 8 wherein the developer discharge nozzle comprises a slit nozzle having a slit-like outlet at a lower end face.

13. The substrate processing apparatus of claim 8 wherein the developer discharge nozzle comprises a straight nozzle having a tip end outlet.

14. A substrate processing apparatus comprising:
substrate holding means for holding a substrate in a horizontal posture;
substrate rotating means causing the substrate that is held by the substrate holding means to rotate about a vertical axis;
a developer discharge nozzle discharging a developer onto a resist film having been exposed and formed on a surface of the substrate held by the substrate holding means; and
a rinse discharge nozzle discharging a rinse onto a resist film having been processed and formed on the substrate surface,
wherein there is provided control means for controlling each of the substrate rotating means, the developer discharge nozzle, and the rinse discharge nozzle such that while the substrate is being rotated by the substrate rotating means, after the developer has been discharged onto the resist film having been exposed and formed on the substrate surface from the developer discharge nozzle to process the resist film, the substrate continues to be rotated, and thus the developer on the surface of the substrate is dispersed by a centrifugal force to be removed, and thereafter a rinse is discharged onto the resist film having been processed and formed on the substrate surface from the rinse discharge nozzle to conduct rinsing.

15. The substrate processing apparatus of claim 14 wherein the developer discharge nozzle, while the developer is being discharged onto the surface of the substrate from an outlet thereof, is scanned from a position in which the outlet is opposed to the center of the surface to a position in which it is opposed to the circumferential edge of the substrate.

16. The substrate processing apparatus of claim 14 further comprising a gas jet nozzle blowing out a drying gas onto the resist film having been processed and formed on the substrate surface.

17. The substrate processing apparatus of claim 16 wherein the gas jet nozzle, while a drying gas is being blown out onto the surface of the substrate from a jet hole thereof, is scanned from a position in which the jet hole is opposed to the center of the substrate to a position in which it is opposed to the circumferential edge of the substrate.

18. The substrate processing apparatus of claim 14 wherein the developer discharge nozzle comprises a slit nozzle having a slit-like outlet at a lower end face.

19. The substrate processing apparatus of claim 14 wherein the developer discharge nozzle comprises a straight nozzle having a tip end outlet.
